(19) United States
(12) Patent Application Publication
(10) Pub. No.: US 2025/0324567 A1
(43) Pub. Date: Oct. 16, 2025

(54) MEMORY DEVICE AND MANUFACTURING METHOD THEREOF

(71) Applicant: YANGTZE MEMORY TECHNOLOGIES CO., LTD., Wuhan (CN)

(72) Inventors: Yuhuan Zheng, Wuhan (CN); Yonggang Yang, Wuhan (CN)

(21) Appl. No.: 18/750,937

(22) Filed: Jun. 21, 2024

(30) Foreign Application Priority Data
Apr. 12, 2024 (CN) 202410444946.0

(51) Int. Cl. H10B 12/00

(52) U.S. Cl. CPC H10B 12/315; H10B 12/05

(57) ABSTRACT

According to one aspect of the present disclosure, a memory device is provided. The memory device may include a first semiconductor structure. The first semiconductor structure may include a semiconductor body extending along a first direction. The first semiconductor structure may include a gate structure located between adjacent semiconductor bodies. The first semiconductor structure may include a bit line extending along a second direction and connected to a first end of two ends of the semiconductor body that are opposite to each other along the first direction. The first direction may be perpendicular to the second direction. The first semiconductor structure may include a first cavity located between the bit line and the gate structure.

### CROSS-REFERENCE TO RELATED APPLICATIONS

The present application claims the benefit of priority to Chinese Application No. 202410444946.0, filed on Apr. 12, 2024, which is hereby incorporated by reference in its entirety.

### TECHNICAL FIELD

The present disclosure relates to the technical field of semiconductors, and for example, to a memory device and a manufacturing method thereof.

### BACKGROUND

With the continuous development of today's science and technology, semiconductor devices are widely used in a variety of electronic apparatuses and electronic products. For example, Dynamic Random Access Memory (DRAM) as a volatile memory is a semiconductor memory device commonly used in computers.

### SUMMARY

According to one aspect of the present disclosure, a memory device is provided. The memory device may include a first semiconductor structure. The first semiconductor structure may include a semiconductor body extending along a first direction. The first semiconductor structure may include a gate structure located between adjacent semiconductor bodies. The first semiconductor structure may include a bit line extending along a second direction and connected to a first end of two ends of the semiconductor body that are opposite to each other along the first direction. The first direction may be perpendicular to the second direction. The first semiconductor structure may include a first cavity located between the bit line and the gate structure.

In some implementations, a size of the first cavity along the second direction may range from 10 nm to 60 nm, or a size of the first cavity along the first direction may range from 10 nm to 100 nm.

In some implementations, the first semiconductor structure may include a plurality of the semiconductor bodies, which include a plurality of semiconductor body groups, the semiconductor body group may include a first semiconductor body and a second semiconductor body, which both extend along the first direction and are arranged along the second direction, the plurality of semiconductor body groups may be arranged in an array along the second direction and a third direction, the third direction may be perpendicular to the first direction and intersects with the second direction. In some implementations, the gate structure extends along the third direction and may be located between the first semiconductor body and the second semiconductor body of the semiconductor body group.

In some implementations, the first cavity may extend along the third direction.

In some implementations, a shape of a first surface of the gate structure may be curved, and the first surface may be a surface, proximate to the bit line, of two surfaces of the gate structure that are opposite to each other along the first direction.

In some implementations, the first semiconductor structure may further include a dielectric layer, which is located between the first semiconductor body and the second semiconductor body of the semiconductor body group, and is located on a side surface of the first semiconductor body, on a side surface of the second semiconductor body, on a surface, proximate to the bit line, of two surfaces of the gate structure that are opposite to each other along the first direction, and on a surface, proximate to the gate structure, of two surfaces of the bit line that are opposite to each other along the first direction.

In some implementations, a shape of a surface, proximate to the bit line, of two surface of a portion of the dielectric layer covering the gate structure that are opposite to each other along the first direction may be the same as a shape of the surface, proximate to the bit line, of the two surfaces of the gate structure that are opposite to each other along the first direction.

In some implementations, the first semiconductor structure may further include a second cavity, which is located between adjacent two of the semiconductor body groups along the second direction.

In some implementations, a size of the second cavity along the second direction may range from 10 nm to 60 nm.

In some implementations, the dielectric layer may be further located between the semiconductor body groups adjacent to each other along the second direction, and may be located on the side surface of the first semiconductor body, on the side surface of the second semiconductor body, and on the surface, proximate to the gate structure, of the two surfaces of the bit line that are opposite to each other along the first direction.

In some implementations, the first semiconductor structure may further include a third cavity, which is located between the bit lines adjacent to each other along the third direction.

In some implementations, the third cavity may communicate with both the second cavity and the first cavity.

In some implementations, a size of the third cavity along the third direction may range from 5 nm to 50 nm.

In some implementations, the dielectric layer may be further located on a side surface of the bit line.

In some implementations, the gate structure may include a first gate layer and a second gate layer arranged in a juxtaposed manner along the second direction, and the first gate layer and the second gate layer may both extend along the third direction.

In some implementations, the memory device may further include a second semiconductor structure. In some implementations, the first semiconductor structure may be stacked with the second semiconductor structure along the first direction, and the second semiconductor structure may include a peripheral circuit.

In some implementations, the first semiconductor structure may further include a plurality of storage structures, a second end of the two ends of the semiconductor body that are opposite to each other along the first direction may be connected to the storage structure.

According to another aspect of the present disclosure, a method of manufacturing a memory device is provided. The method may include forming a first semiconductor structure. The forming the first semiconductor structure may include forming a semiconductor body extending along a first direction. The forming the first semiconductor structure may include forming a gate structure located between adjacent semiconductor bodies. The forming the first semiconductor structure may include forming a bit line, extending along a second direction and connected to a first end of two ends of the semiconductor body that are opposite to each other along the first direction. The first direction may be perpendicular to the second direction. The forming the first semiconductor structure may include forming a first cavity located between the bit line and the gate structure.

In some implementations, the forming the semiconductor body and forming the bit line may include forming a plurality of semiconductor body groups and a plurality of initial bit lines. In some implementations, the plurality of semiconductor body groups may be arranged in an array along the second direction and a third direction. In some implementations, the semiconductor body group may include a first semiconductor body and a second semiconductor body, which both extend along the first direction and are arranged along the second direction. In some implementations, the initial bit line may extend along the second direction and may be located on a first side of the semiconductor body group. In some implementations, the second direction and the third direction intersect with each other and both are perpendicular to the first direction. In some implementations, the forming the gate structure and forming the first cavity may include forming a first sacrificial structure between the first semiconductor body and the second semiconductor body of the semiconductor body group from a second side. In some implementations, the first sacrificial structure may extend along the third direction, and a size of the first sacrificial structure along the first direction may be less than a size of the semiconductor body group along the first direction. In some implementations, the first side and the second side may be sides of the plurality of semiconductor body groups that are opposite to each other along the first direction. In some implementations, the forming the gate structure and forming the first cavity may include forming an initial gate structure covering the first sacrificial structure between the first semiconductor body and the second semiconductor body of the semiconductor body group from the second side. In some implementations, the forming the gate structure and forming the first cavity may include removing the first sacrificial structure and a part of the initial gate structure from the first side to form the gate structure and the first cavity.

In some implementations, the initial gate structure may include two side portions and one bottom portion; the side portions extend along the first direction, the bottom portion extends along the second direction and connects the two side portions. In some implementations, the removing the first sacrificial structure and the part of the initial gate structure from the first side to form the gate structure and the first cavity may include removing the first sacrificial structure from the first side to expose the bottom portion of the initial gate structure, and removing the exposed bottom portion from the first side to form the first cavity and a first gate layer and a second gate layer respectively included by the two side portions.

In some implementations, the forming the first semiconductor structure may further include, before forming the first sacrificial structure, forming a second sacrificial structure between the semiconductor body groups from the second side. In some implementations, the second sacrificial structure may extend along the third direction. In some implementations, the forming the first semiconductor structure may further include removing the second sacrificial structure from the first side to form a second cavity.

In some implementations, removing the first sacrificial structure and removing the second sacrificial structure may be performed at the same time.

In some implementations, the forming the first semiconductor structure may further include forming a metal material layer on the initial bit line from the first side. In some implementations, the forming the first semiconductor structure may further include performing heat treatment on the metal material layer and the initial bit line to form the bit line.

In some implementations, the forming the first semiconductor structure may further include, before forming the metal material layer on the initial bit line from the first side, forming third sacrificial structures in the first cavity, in the second cavity, and between adjacent initial bit lines. In some implementations, the forming the first semiconductor structure may further include, after forming the bit line, removing the third sacrificial structures to form third cavities between adjacent bit lines.

In some implementations, the forming the first semiconductor structure may include, after removing the third sacrificial structures, forming, from the first side, dielectric layers on an exposed surface of the first semiconductor body, an exposed surface of the second semiconductor body, an exposed surface of the gate structure, and an exposed surface of the bit line.

In some implementations, the forming the plurality of semiconductor body groups and the plurality of initial bit lines may include providing a base structure, and etching the base structure from the second side to form a plurality of first grooves. In some implementations, the plurality of first grooves may all extend along the second direction and may be arranged along the third direction. In some implementations, the forming the plurality of semiconductor body groups and the plurality of initial bit lines may include etching the base structure from the second side to form a plurality of second grooves. In some implementations, the plurality of second grooves may all extend along the third direction and may be arranged along the second direction. In some implementations, the forming the plurality of semiconductor body groups and the plurality of initial bit lines may include forming a fourth sacrificial structure in the second groove. In some implementations, the forming the plurality of semiconductor body groups and the plurality of initial bit lines may include etching the base structure from the second side to form a plurality of third grooves. In some implementations, the plurality of third grooves may all extend along the third direction and may be arranged along the second direction, and the second grooves and the third grooves may be alternately arranged along the second direction, depths of the first grooves may be greater than depths of the second grooves and depths of the third grooves, the first grooves, the second grooves, and the third grooves may divide the base structure into the plurality of semiconductor body groups and the plurality of initial bit lines.

In some implementations, the forming the second sacrificial structure may include forming the second sacrificial structure in the third groove. In some implementations, the forming the first semiconductor structure may further include, after forming the second sacrificial structure, removing the fourth sacrificial structure from the second side.

In some implementations, the forming the first semiconductor structure may further include forming a plurality of storage structures. In some implementations, a second end of the two ends of the semiconductor body that are opposite to each other along the first direction may be connected to one of the storage structures.

In some implementations, the method may further include forming a second semiconductor structure. In some implementations, the second semiconductor structure may be a peripheral circuit. In some implementations, the method may include bonding the first semiconductor structure and the second semiconductor structure.

According to a further aspect of the present disclosure, a memory system is provided. The memory system may include a memory device. The memory device may include a semiconductor structure. The semiconductor structure may include a semiconductor body extending along a first direction. The semiconductor structure may include a gate structure located between adjacent semiconductor bodies. The semiconductor structure may include a bit line extending along a second direction and connected to a first end of two ends of the semiconductor body that are opposite to each other along the first direction. The first direction may be perpendicular to the second direction. The semiconductor structure may include a first cavity located between the bit line and the gate structure. The memory system may include a controller coupled to the memory device and configured to control at least one operation of the memory device.

### BRIEF DESCRIPTION OF THE DRAWINGS

FIG. 1 is a schematic structural diagram of an electronic apparatus provided by an example of the present disclosure.

FIG. 2 is a schematic structural diagram of a memory provided by an example of the present disclosure.

FIG. 3 is a flow chart of a formation method of a memory device provided by an example of the present disclosure.

FIGS. 4 to 42 are schematic structural diagrams of a formation process of a memory device provided by an example of the present disclosure.

FIG. 43 is a schematic cross-sectional view I of a structure of a memory device provided by an example of the present disclosure.

FIG. 44 is a schematic top view of a structure of a memory device provided by an example of the present disclosure.

FIG. 45 is a schematic cross-sectional view II of a structure of a memory device provided by an example of the present disclosure.

### DETAILED DESCRIPTION

Exemplary implementations disclosed in the present disclosure are described below in more detail with reference to the drawings. Although the exemplary implementations of the present disclosure are shown in the drawings, it should be understood that the present disclosure may be implemented in various forms and should not be limited by the implementations described here. On the contrary, these implementations are provided for more thorough understanding of the present disclosure, and to fully convey a scope disclosed in the present disclosure to those skilled in the art.

In the following descriptions, a lot of details are given in order to provide the more thorough understanding of the present disclosure. However, it is apparent to those skilled in the art that the present disclosure may be implemented without one or more of these details. In other examples, in order to avoid confusion with the present disclosure, some technical features well-known in the field are not described. That is, not all the features of the actual examples are described here, and well-known functions and structures are not described in detail.

In the drawings, like reference numerals denote like elements throughout the specification.

It is to be understood that, spatially relative terms, such as “beneath”, “below”, “lower”, “under”, “over”, “upper”, etc., may be used here for ease of description to describe the relationship between one element or feature and other elements or features as illustrated in the figures. It is to be understood that the spatially relative terms are intended to further encompass different orientations of a device in use or operation in addition to the orientation depicted in the figures. For example, if the device in the drawings is flipped, then the elements or the features described as “below” or “under” or “beneath” other elements may be oriented “on” the other elements or features. Thus, the example terms “below” and “beneath” may comprise both upper and lower orientations. The device may be orientated otherwise (rotated by 90 degrees or other orientations), and the spatially descriptive terms used here are interpreted accordingly.

The terms used here are only intended to describe the specific examples, and are not used as limitations to the present disclosure. As used here, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more other features, integers, steps, operations, elements, components, and/or groups. As used here, a term “and/or” comprises any and all combinations of related items listed.

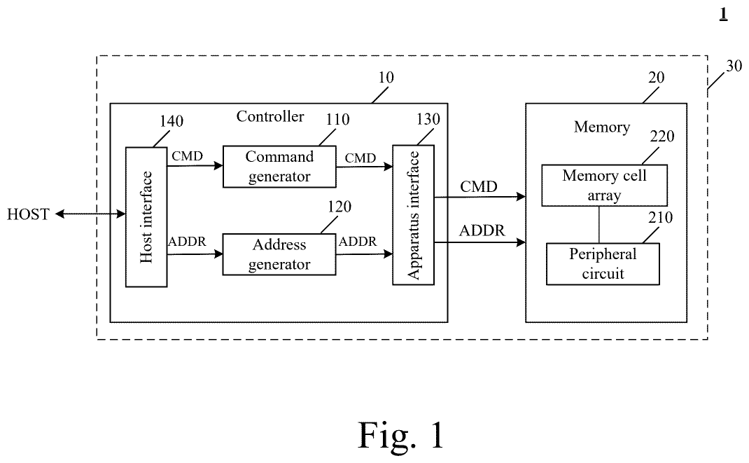

FIG. 1 is a schematic diagram of an electronic apparatus 1 shown according to an example of the present disclosure. The electronic apparatus 1 can be a mobile phone, a desktop computer, a laptop computer, a tablet, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having the memories therein.

As shown in FIG. 1, the electronic apparatus 1 may include a host HOST and a memory system 30, and the memory system 30 is provided with one or more memories 20 and a controller 10. The host HOST may include a processor of an electronic apparatus, such as a Central Processing Unit (CPU), or a System on Chip (SoC), such as an Application Processor (AP). The host HOST may be configured to send or receive data to or from the memory 20. The controller 10 is coupled to the memory 20 and the host HOST, and is configured to control the memory 20. The controller 10 may manage data stored in the memory 20, and communicate with the host HOST.

The controller 10 may be configured to control operations of the memory 20, such as read, erase, write, and refresh operations. In some implementations, the controller 10 is further configured to process Error Correction Codes (ECC) with respect to the data read from or written to the memory 20. The controller 10 may further perform any other suitable functions, for example, formatting the memory 20.

In some examples, the controller 10 and one or more memories 20 may all be integrated into various types of storage apparatuses. For example, the controller 10 may be integrated at a north bridge of a computer mainboard or directly integrated into a CPU of a computer, and the plurality of memories 20 may be integrated into a memory bank. In other words, the memory system 30 may be implemented and packaged into different types of end electronic products.

The controller 10 may send or receive data to or from the host HOST, and may send a command CMD and an address ADDR to the memory 20. The controller 10 may include a command generator 110, an address generator 120, an apparatus interface 130, and a host interface 140. The host interface 140 may receive the command CMD and the address ADDR from the host HOST; and the command generator 110 may generate an access command, a refresh command, and the like by decoding the command CMD received from the host HOST, and may provide the access command and the refresh command to the memory 20 through the apparatus interface 130. The access command may be a signal that instructs the memory 20 to write or read data by accessing rows of a memory cell array 220 corresponding to the address ADDR. The refresh command may be a signal that instructs the memory 20 to read and re-write the data by accessing and refreshing the rows of the memory cell array 220 corresponding to the address ADDR.

The address generator 120 in the controller 10 may generate a row address and a column address to be accessed in the memory cell array 220 by decoding the address ADDR received from the host interface 140. Furthermore, the memory 20 may generate an address of a bank to be accessed when the memory cell array 220 includes a plurality of banks.

The controller 10 may provide various signals to the memory 20 via the apparatus interface 130 to control memory operations such as write and read. For example, the controller 10 may provide a write command to the memory 20. The write command is used for instructing the memory 20 to perform a write operation to store data in the memory 20.

In some examples, the memory 20 includes at least one chip, each chip includes at least one bank, each bank includes at least one block, each block includes the memory cell array 220 and a peripheral circuit 210; and the memory cell array includes a plurality of memory cell rows and a plurality of memory cell columns, each memory cell row is coupled with one corresponding word line, and each memory cell column is coupled with one corresponding bit line. The peripheral circuit 210 may write or read data to or from the memory cell array 220 based on the command CMD and the address ADDR received from the controller 10, or may provide a control signal CTRL for refreshing memory cells included in the memory cell array 220 to a row decoder and a column decoder. In other words, the peripheral circuit 210 may perform all operations to process the data stored in the memory cell array 220. The peripheral circuit 210 may include: a control circuit corresponding to each block, such as a Sensing Amplifier (SA) circuit, a Word-Line Driver (WLD) circuit, etc.; a control circuit corresponding to each bank, such as the row decoder, the column decoder, etc.; and a control circuit corresponding to all banks, such as a command buffer, a command decoder, an address buffer, a data input/output buffer, a mode register, etc.

The memory 20 may be a Random Access Memory (RAM) such as a Dynamic Random Access Memory (DRAM), a Synchronous DRAM (SDRAM), a Static RAM (SRAM), a Double Data Rate SDRAM (DDR SDRAM), a DDR2 SDRAM, a DDR3 SDRAM, a Phase-change RAM (PRAM), a Magnetic RAM (MRAM), a Resistive RAM (RRAM), etc. The following is described by only using an example that the memory is the DRAM.

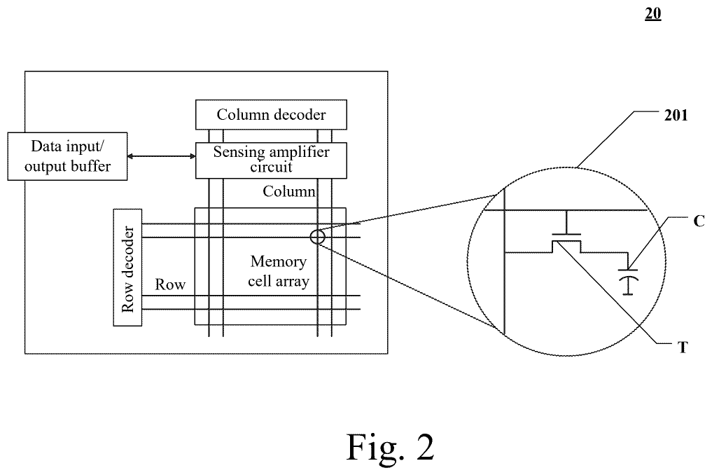

FIG. 2 is a schematic diagram of a dynamic random access memory shown according to an example of the present disclosure. Referring to FIG. 2, the dynamic random access memory includes the memory cell array and the peripheral circuit. The memory cell array includes a plurality of memory cells 201 arranged in an array, each memory cell 201 includes one transistor T and one capacitor C, a word line is coupled to a gate of the transistor T, and a bit line is coupled to a drain of the transistor T. A main action principle of the memory cell is to utilize the number of charges stored in the capacitor to represent whether one binary bit is 1 or 0. The memory cells are arranged in an array, and the memory cell array employs rows and columns to designate addresses. By designating intersections of the rows and the columns (by designating row addresses and column addresses of the DRAM), the controller may independently access each memory cell in a DRAM chip, and perform read, write, or refresh operations on data stored in the memory cell.

With the development of a dynamic random access memory technology, a size of the memory cell becomes smaller and smaller, an array architecture thereof is from 8F² to 6F², and then to 4F², and an architecture of the transistor in the memory cell is also gradually developed from a planar array transistor to a vertical gate transistor, thereby forming an architecture of a three-dimensional memory.

In some examples, the formation of the word line in the architecture of the vertical gate transistor may be that a U-shaped conductive layer is formed on a front face of a substrate, and a dielectric layer is formed at a bottom portion of the U-shaped conductive layer, so as to control a height of the bottom portion of the U-shaped conductive layer. Then, the bottom portion of the U-shaped conductive layer is etched from the front face of the substrate, e.g., disconnect processing is performed on the U-shaped conductive layer to form two separate word lines. In the above-mentioned examples, the bottom portion of the U-shaped conductive layer is etched from the front face of the substrate, resulting in relatively large process complexity. In some other examples, the formation of the word line in the architecture of the vertical gate transistor may be that the U-shaped conductive layer is formed on the front face of the substrate; the bottom portion of the U-shaped conductive layer is removed from a back face of the substrate, e.g., disconnect processing is performed on the U-shaped conductive layer; and a part of a side portion of the conductive layer is removed from the back face of the substrate, so as to control a height of the side portion of the conductive layer. However, in the examples, when the part of the side portion of the conductive layer is removed from the back face of the substrate, the height of the side portion of the conductive layer is relatively difficult to be well controlled, and the heights of the side portions of the plurality of conductive layers are relatively difficult to be homogenized, thereby affecting the performance of the memory.

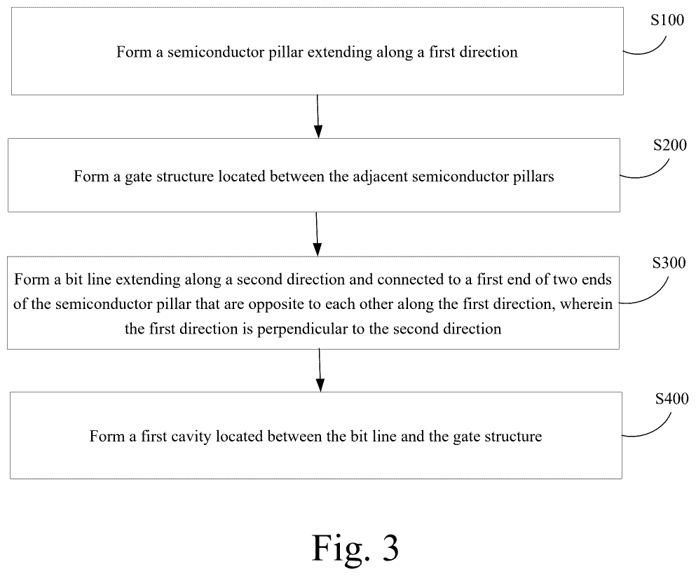

In view of one or more of the above-mentioned problems, an example of the present disclosure provides a manufacturing method of a memory device. The manufacturing method includes forming a first semiconductor structure. As shown in FIG. 3, forming the first semiconductor structure includes the following operations.

Operation S100: forming a semiconductor body, where the semiconductor body extends along a first direction.

Operation S200: forming a gate structure, where the gate structure is located between the adjacent semiconductor bodies.

Operation S300: forming a bit line, where the bit line extends along a second direction and connected to a first end of two ends of the semiconductor body that are opposite to each other along the first direction; and the first direction is perpendicular to the second direction.

Operation S400: forming a first cavity, where the first cavity is located between the bit line and the gate structure.

It is to be understood that the operations shown in FIG. 3 are not exclusive, and other operations may be performed as well before, after, or between any of the shown operations. A sequence of the operations shown in FIG. 3 may be adjusted according to actual requirements.

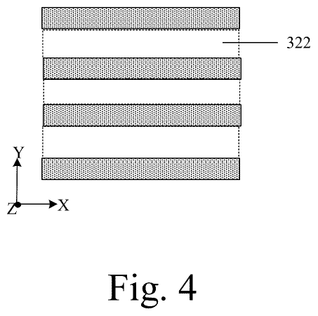

FIGS. 4 to 42 are schematic diagrams of a formation process of a memory device shown according to an example of the present disclosure. A formation method of a memory device provided by an example of the present disclosure will be exemplarily described below in conjunction with FIGS. 4 to 42.

In some examples, forming the semiconductor body and forming the bit line may include: forming a plurality of semiconductor body groups and a plurality of initial bit lines, where the plurality of semiconductor body groups are arranged in an array along the second direction and a third direction; the semiconductor body group includes a first semiconductor body and a second semiconductor body extending along the first direction and arranged along the second direction; the initial bit line extends along the second direction and is located on a first side of the semiconductor body group; and the second direction and the third direction intersect with each other and both are perpendicular to the first direction.

The intersection between the second direction and the third direction here is exemplarily described by using an example that the second direction is perpendicular to the third direction in the examples of the present disclosure. In some examples, the first direction may be a Z-axis direction in the drawings of the present disclosure, the second direction may be an X-axis direction in the drawings of the present disclosure, and the third direction may be a Y-axis direction in the drawings of the present disclosure.

In some examples, as shown in FIGS. 4 to 14, the forming the plurality of semiconductor body groups 307 and the plurality of initial bit lines 306 includes: providing a base structure 321, and etching the base structure 321 from the second side to form a plurality of first grooves 322, where the plurality of first grooves 322 all extend along the second direction and are arranged along the third direction; etching the base structure 321 from the second side to form a plurality of second grooves 323, where the plurality of second grooves 323 all extend along the third direction and are arranged along the second direction; forming fourth sacrificial structures 324 in the second grooves 323; and etching the base structure 321 from the second side to form a plurality of third grooves 325, where the plurality of third grooves 325 all extend along the third direction and are arranged along the second direction, and the second grooves 323 and the third grooves 325 are alternately arranged along the second direction; depths of the first grooves 322 are greater than depths of the second grooves 323 and depths of the third grooves 325; the first grooves 322, the second grooves 323, and the third grooves 325 divide the base structure 321 into the plurality of semiconductor body groups 307 and the plurality of initial bit lines 306.

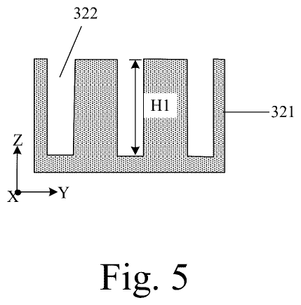

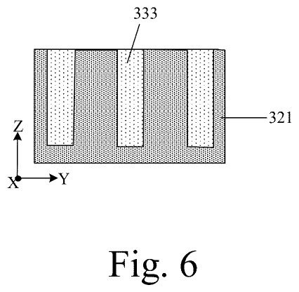

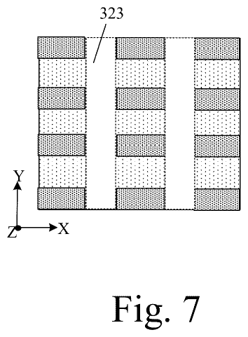

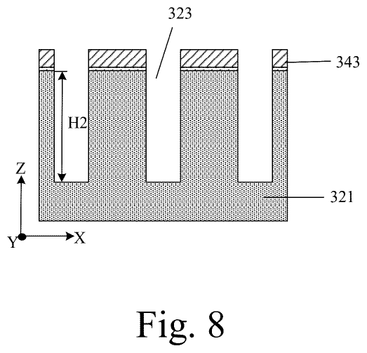

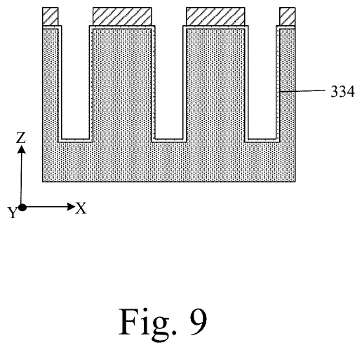

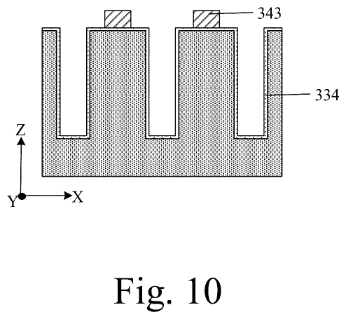

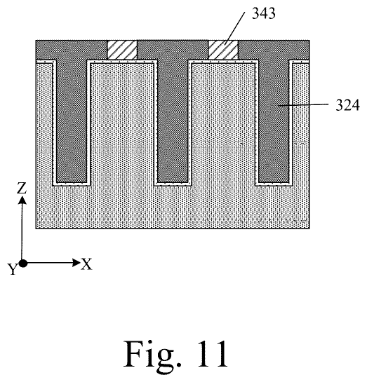

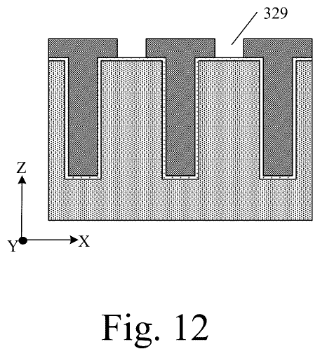

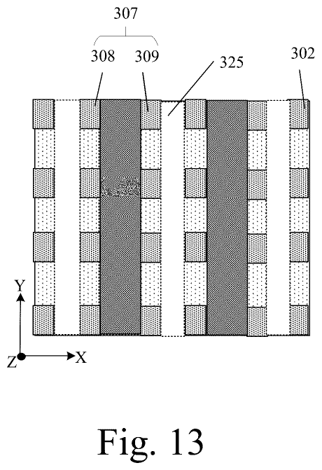

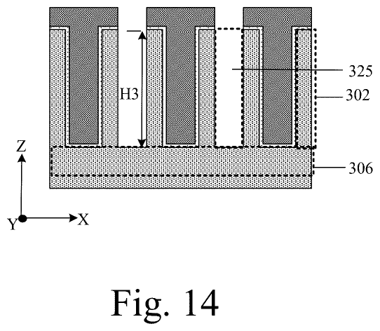

The base structure 321 includes the first side and the second side, which are opposite to each other along the first direction. As shown in FIGS. 4 and 5, the first groove 322 is formed through dry etching from the second side of the base structure 321, and the depth of the first groove 322 is H1. As shown in FIG. 6, a first dielectric layer 333 may be filled in the first groove 322 through a deposition process. As shown in FIGS. 7 and 8, a patterned mask layer 343 is formed on the base structure 321 from the second side of the base structure 321, and then the second groove 323 is formed through the dry etching process; and the depth of the second groove 323 is H2, where H1>H2. As shown in FIG. 9, a surface of the base structure 321 that is exposed from the second groove 323 is oxidized from the second side of the base structure 321 so that a second dielectric layer 334 is formed on the exposed surface of the base structure 321. As shown in FIG. 10, part of the mask layer 343 is removed from the second side of the base structure 321, and the remaining mask layer 343 covers partial top surface of the base structure 321 between the second grooves 323. As shown in FIG. 11, a fourth sacrificial structure 324 is formed in the second groove 323 from the second side of the base structure 321, the fourth sacrificial structure 324 is also formed on the top surface of the base structure 321, and a top face of the fourth sacrificial structure 324 is flush with a top face of the mask layer 343. As shown in FIG. 12, the remaining mask layer 343 is removed from the second side of the base structure 321 to form a fourth groove 329, and the fourth groove 329 extends along the third direction. As shown in FIGS. 13 and 14, the base structure 321 is etched through the fourth groove 329 from the second side of the base structure 321 to form the third groove 325, where the third groove 325 extends along the third direction, and the depth of the third groove 325 is H3, where H1>H3, and H2 and H3 may or may not be equal.

The first grooves 322, the second grooves 323, and the third grooves 325 divide the base structure 321 into the plurality of semiconductor body 302 and the plurality of initial bit lines 306. The plurality of semiconductor bodies constitute the plurality of semiconductor body groups 307, where the semiconductor body group 307 includes a first semiconductor body 308 and a second semiconductor body 309 arranged along the second direction, the initial bit line 306 extends along the second direction, and the plurality of initial bit lines 306 are arranged along the third direction. In subsequent processes, the base structure 321 may be thinned from the first side of the base structure 321, so as to expose the first dielectric layer 333. Here, the first side of the base structure 321 and a first side of the semiconductor body group 307 may be understood as the same side, and the second side of the base structure 321 and a second side of the semiconductor body group 307 may be understood as the same side.

FIG. 4 is a schematic top view of the structure of FIG. 5. FIG. 7 is a schematic top view of the structure of FIG. 8. FIG. 13 is a schematic top view of the structure of FIG. 14. It is to be noted that, FIGS. 4, 7, and 13 are perspective views, in which partial structures are omitted.

In an example of the present disclosure, the deposition process includes, but is not limited to, Chemical Vapor Deposition (CVD), Low Pressure Chemical Vapor Deposition (LPCVD), Plasma Enhanced Chemical Vapor Deposition (PECVD), Physical Vapor Deposition (PVD), and Atomic Layer Deposition (ALD).

In some examples, a material of the first dielectric layer 333 includes, but is not limited to, silicon nitride and silicon oxide, and a material of the second dielectric layer 334 includes, but is not limited to, silicon oxide. A material of the fourth sacrificial structure 324 includes, but is not limited to, tungsten. When the material of the fourth sacrificial structure 324 is selected, it needs to be taken into consideration that, when the third groove and the fourth groove are formed in the subsequent processes, the impact on the fourth sacrificial structure 324 is within an acceptable range. Furthermore, it needs to be taken into consideration that, the impact on a fourth dielectric layer 336 is within the acceptable range when the fourth sacrificial structure 324 is removed in the subsequent processes.

In some examples, forming the first semiconductor structure further includes: before forming the first sacrificial structure, forming a second sacrificial structure between the semiconductor body groups from the second side, where the second sacrificial structure extends along the third direction.

In some examples, forming the second sacrificial structure includes: forming the second sacrificial structure in the third groove. Forming the first semiconductor structure further includes: after forming the second sacrificial structure, removing the fourth sacrificial structure from the second side.

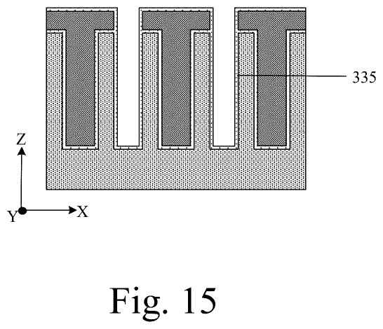

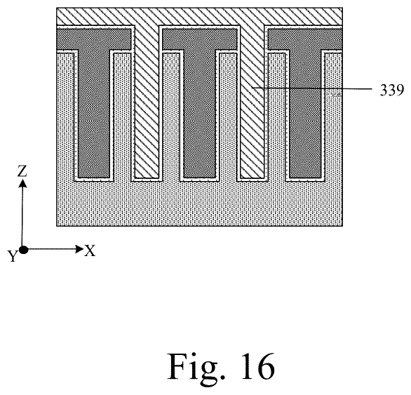

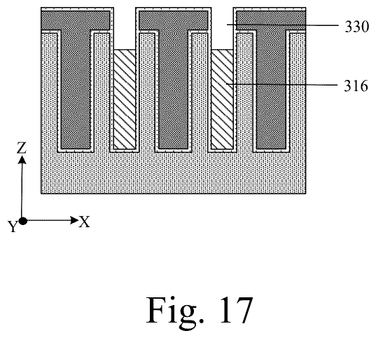

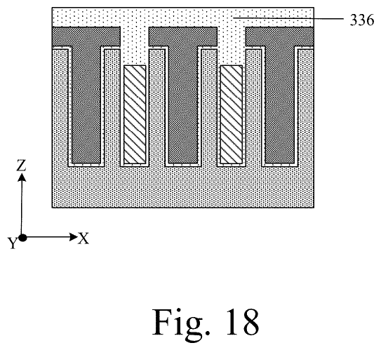

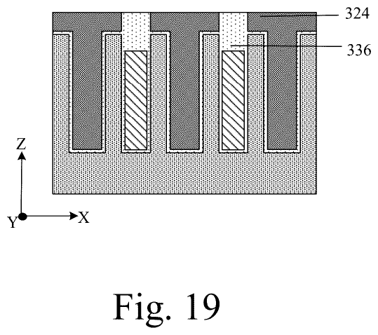

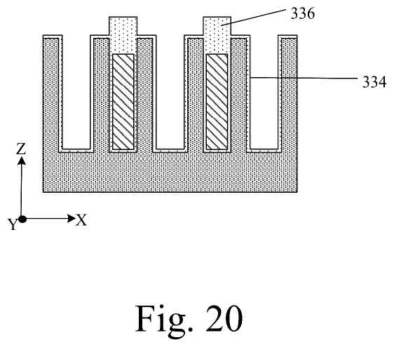

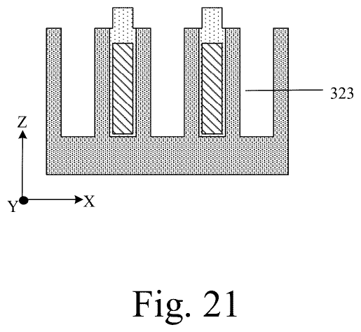

As shown in FIG. 15, a third dielectric layer 335 covering a side wall of the fourth groove 329, a side wall of the third groove 325, a bottom wall of the third groove 325, and the top surface of the fourth sacrificial structure 324 is formed through the deposition process. As shown in FIG. 16, second sacrificial layers 339 are formed in the third groove 325 and the fourth groove 329, and the second sacrificial layer 339 is also formed on the fourth sacrificial structure 324. As shown in FIG. 17, a part of the second sacrificial layer 339 is removed to form a fifth groove 330 located between the adjacent fourth sacrificial structures 324, a top surface of the remaining second sacrificial layer 339 is lower than the top surface of the base structure 321, and the remaining second sacrificial layer 339 constitutes the second sacrificial structure 316. As shown in FIG. 18, the fourth dielectric layer 336 is formed in the fifth groove 330 and on the fourth sacrificial structure 324. As shown in FIG. 19, a part of the fourth dielectric layer 336 is removed by utilizing a planarization process, and a top surface of the remaining fourth dielectric layer 336 is flush with the top surface of the fourth sacrificial structure 324. As shown in FIG. 20, the fourth sacrificial structure 324 may be removed through a wet etching process. As shown in FIG. 21, the second dielectric layer 334 is removed from the first side.

In some examples, a material of the third dielectric layer 335 includes, but is not limited to, silicon oxide and silicon nitride, and a material of the fourth dielectric layer 336 includes, but is not limited to, silicon oxide and silicon nitride. A material of the second sacrificial structure 316 includes, but is not limited to, at least one of titanium nitride, silicon nitride, carbon, tungsten, molybdenum, or aluminum oxide.

In some examples, the base structure 321 may be a substrate. The substrate may include an elementary semiconductor material substrate (e.g., a Silicon (Si) substrate, a germanium (Ge) substrate, etc.), a composite semiconductor material substrate (e.g., a silicon germanium (SiGe) substrate), a Silicon-On-Insulator (SOI) substrate, Germanium-On-Insulator (GeOI) substrate, etc. Preferably, the substrate is the Si substrate.

In some examples, forming the gate structure and forming the first cavity may include: forming the first sacrificial structure between the first semiconductor body and the second semiconductor body of the semiconductor body group from a second side, where the first sacrificial structure extends along the third direction, and a size of the first sacrificial structure along the first direction is less than a size of the semiconductor body group along the first direction; the first sides and the second sides are sides of the plurality of semiconductor body groups that are opposite to each other along the first direction.

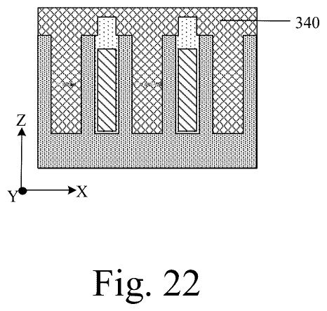

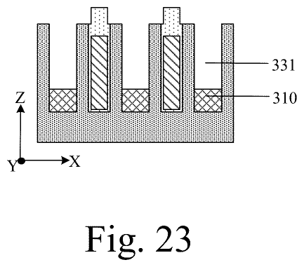

In some examples, as shown in FIG. 22, a first sacrificial layer 340 is formed in the second groove 323, and the first sacrificial layer 340 is also formed on the top surface of the base structure 321. As shown in FIG. 23, a part of the first sacrificial layer 340 is removed to form a sixth groove 331 so that a top surface of the remaining first sacrificial layer 340 is lower than the top surface of the base structure 321 and the remaining first sacrificial layer 340 constitutes the first sacrificial structure 310. The sixth groove 331 here is located between the first semiconductor body 308 and the second semiconductor body 309 of the semiconductor body group 307, and the sixth groove 331 extends along the third direction.

In some examples, a material of the first sacrificial structure 310 includes, but is not limited to, at least one of titanium nitride, silicon nitride, carbon, tungsten, molybdenum, or aluminum oxide.

In some examples, the material of the first sacrificial structure 310 may be the same as or different from the material of the second sacrificial structure 316. When the material of the first sacrificial structure 310 is the same as the material of the second sacrificial structure 316, removing the first sacrificial structure 310 and removing the second sacrificial structure 316 may be performed at the same time in the subsequent processes. When the material of the first sacrificial structure 310 is different from the material of the second sacrificial structure 316, removing the first sacrificial structure 310 and removing the second sacrificial structure 316 may be performed in steps in the subsequent processes.

In some examples, an initial gate structure covering the first sacrificial structure is formed between the first semiconductor body and the second semiconductor body of the semiconductor body group from the second side.

In some examples, the initial gate structure includes two side portions and one bottom portion, the side portions extend along the first direction, and the bottom portion extends along the second direction and connects the two side portions.

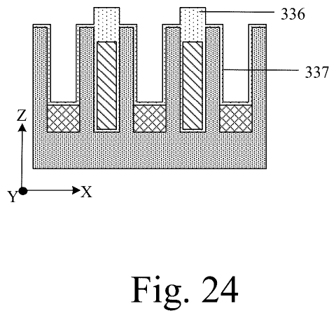

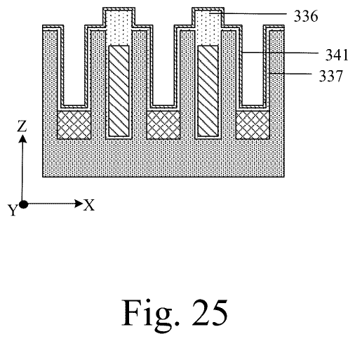

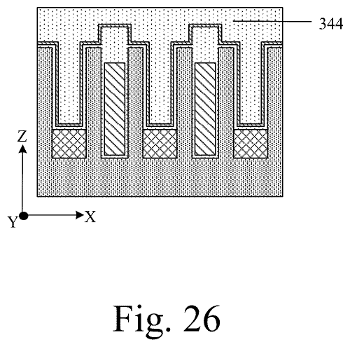

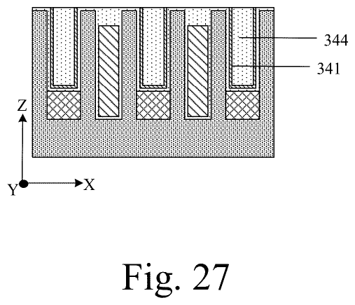

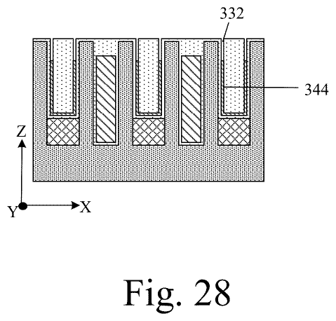

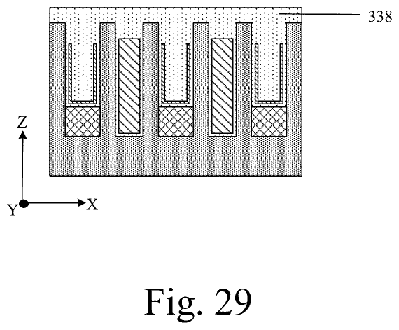

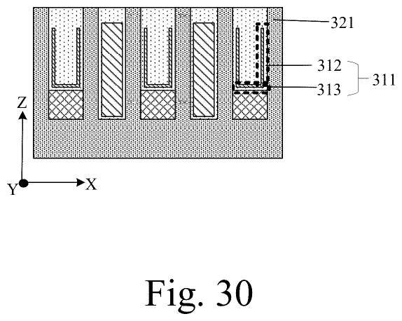

As shown in FIG. 24, a fifth dielectric layer 337 is formed on a side wall of the sixth groove 331, a bottom wall of the sixth groove 331, the top surface of the base structure 321, and the top surface of the fourth dielectric layer 336. As shown in FIG. 25, a first conductive layer 341 covering the fifth dielectric layer 337 is formed. As shown in FIG. 26, a sixth dielectric layer 344 covering the first conductive layer 341 is formed. As shown in FIG. 27, planarization processing is performed to disconnect the first conductive layer 341 in the adjacent sixth grooves 331. As shown in FIG. 28, a part of the first conductive layer 341 is removed to form a seventh groove 332 so that a top surface of the remaining first conductive layer 341 is lower than the top surface of the base structure 321. As shown in FIG. 29, a seventh dielectric layer 338 is formed in the seventh groove 332 and on the base structure 321. As shown in FIG. 30, planarization processing is performed to expose the top surface of the base structure 321. The initial gate structure 311 shown in FIG. 30 includes the remaining first conductive layer 341 and the remaining fifth dielectric layer 337; the initial gate structure 311 extends along the third direction; and the initial gate structure 311 includes two side portions 312 extending along the first direction and two bottom portions 313 extending along the second direction.

In some examples, a material of the fifth dielectric layer 337 includes, but is not limited to, silicon oxide and silicon nitride. A material of the first conductive layer 341 includes, but is not limited to, at least one of titanium nitride or tungsten. The first conductive layer 341 may include a first sub conductive layer and a second sub conductive layer. A material of the sixth dielectric layer 344 includes, but is not limited to, silicon oxide and/or silicon nitride. A material of the seventh dielectric layer 338 includes, but is not limited to, silicon oxide and/or silicon nitride.

In some examples, the first sacrificial structure and a part of the initial gate structure are removed from the first side to form the gate structure and the first cavity.

In some examples, the removing the first sacrificial structure and the part of the initial gate structure from the first side to form the gate structure and the first cavity may include: removing the first sacrificial structure from the first side to expose the bottom portion of the initial gate structure, and removing the exposed bottom portion from the first side to form the first cavity, and a first gate layer and a second gate layer respectively constituted by the two side portions.

In some examples, forming the first semiconductor structure may further include: removing the second sacrificial structure from the first side to form a second cavity.

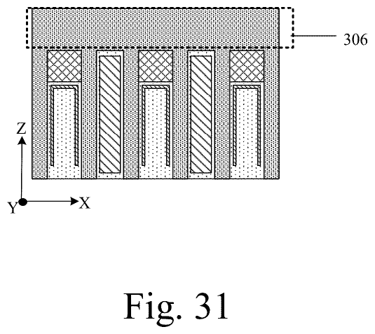

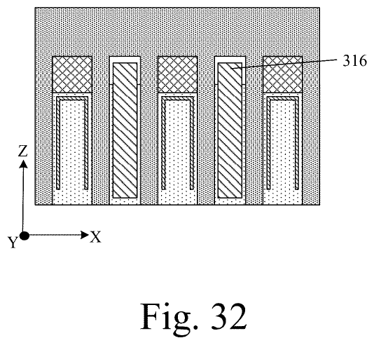

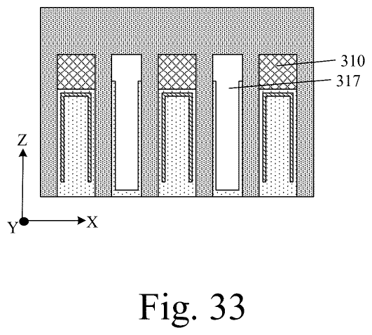

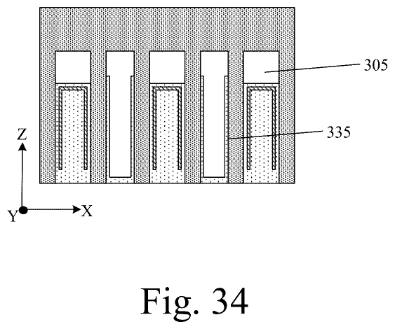

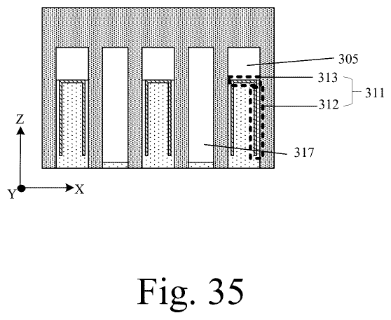

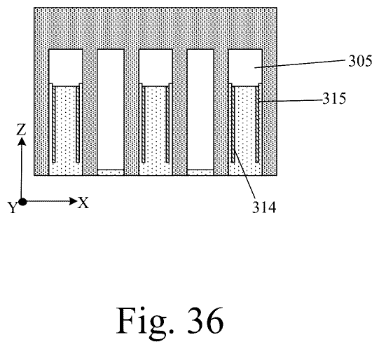

As shown in FIG. 31, the first side of the base structure 321 is enabled to face upward, and the second side is enabled to face downward. In some examples, the base structure 321 may be thinned from the first side to expose the first dielectric layer 333 and the initial bit line 306, and a part of the first dielectric layer 333 is removed to expose the third dielectric layer 335. As shown in FIG. 32, a part of the third dielectric layer 335 is removed from the first side to expose the second sacrificial structure 316. As shown in FIG. 33, the second sacrificial structure 316 is removed from the first side to form the second cavity 317. In some examples, the first sacrificial structure 310 is also exposed while a part of the first dielectric layer 333 is removed to expose the third dielectric layer 335. As shown in FIG. 34, the first sacrificial structure 310 is removed to form the first cavity 305 to expose the bottom portion 313 of the initial gate structure 311. As shown in FIG. 35, the remaining third dielectric layer 335 is removed. Next, as shown in FIG. 36, the exposed bottom portion 313 of the initial gate structure 311 is removed from the first side, the first conductive layers 341 in the two side portions 312 of the remaining initial gate structure 311 respectively constitute a first gate layer 314 and a second gate layer 315, the fifth dielectric layers 337 in the two side portions 312 of the remaining initial gate structure 311 may constitute two gate insulation layers, the first gate layer 314 and the second gate layer 315 here may be word lines.

In an example of the present disclosure, in a first aspect, a disconnecting process of the initial gate structure 311 is performed from a back face (first side) of the base structure 321 to form the first gate layer 314 and the second gate layer 315, it is unnecessary to disconnect the initial gate structure 311 on the front face of the base structure 321, such that the process is associated with a limited complexity. In a second aspect, the first sacrificial structure 310 is first formed at the bottom portion 313 of the initial gate structure 311, and after the first sacrificial structure 310 is removed from the back face (first side) of the base structure 321, the disconnecting process of the initial gate structure 311 is performed, such that a height of the end, close to the bit line, of the two ends of the finally-formed gate structure that are opposite to each other along the first direction can be controlled, e.g., by controlling a size of the first sacrificial structure 310 along the first direction without removing a certain height of the side portion of the initial gate structure 311 from the back face of the base structure 321, thereby causing the height of the end, close to the bit line, of the two ends of the finally-formed gate structure that are opposite to each other along the first direction to be able to be well controlled. Furthermore, the heights of the ends, close to the bit line, of the two ends of different gate structures that are opposite to each other along the first direction have uniformity such that the performance of the memory device can be improved. In a third aspect, the first cavity 305 is formed between the bit line and the gate structure to reduce interference between transistors on two sides of the first cavity 305, such that the performance of the memory device can be improved. In a fourth aspect, the second cavity 317 may be formed from the back face of the base structure 321, such that interference between the transistors on two sides of the second cavity 317 is reduced, and interference between the gate structures on the two sides of the second cavity 317 is reduced.

In some examples, removing the first sacrificial structure 310 and removing the second sacrificial structure 316 are performed at the same time.

It can be understood that, when the materials of the first sacrificial structure 310 and the second sacrificial structure 316 are the same, the removing of the first sacrificial structure 310 and the removing of the second sacrificial structure 316 may be performed at the same time to save process flows, thereby reducing process costs.

In some examples, forming the first semiconductor structure may further include: before forming a metal material layer on the initial bit line from the first side, forming third sacrificial structures in the first cavity, in the second cavity, and between the adjacent initial bit lines.

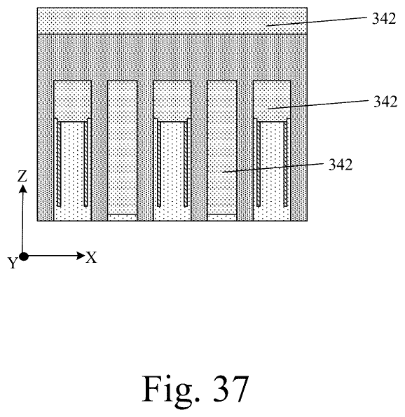

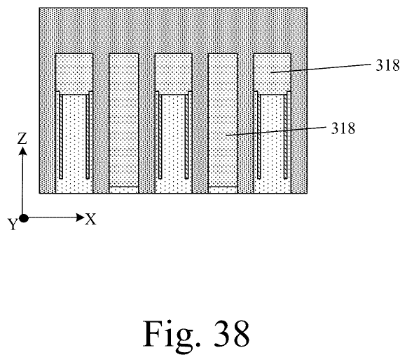

In some examples, a material of the third sacrificial structure 318 includes, but is not limited to, carbon. In some examples, as shown in FIG. 37, a third sacrificial layer 342 is formed in the first cavity 305, in the second cavity 317, between the adjacent initial bit lines 306, and on the first side of the base structure 321. As shown in FIG. 38, planarization processing is performed to remove a part of the third sacrificial layer 342, so as to expose the base structure 321, and the remaining third sacrificial layer 342 constitutes the third sacrificial structure 318.

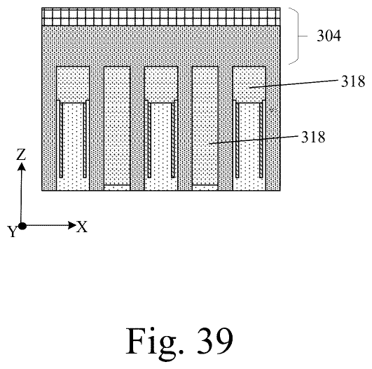

In some examples, as shown in FIGS. 39 to 41, forming the first semiconductor structure further includes: forming the metal material layer on the initial bit line 306 from the first side; performing heat treatment on the metal material layer and the initial bit line 306 to form the bit line 304; and after forming the bit line 304, removing the third sacrificial structure 318 to form a third cavity 319 between the adjacent bit lines 304.

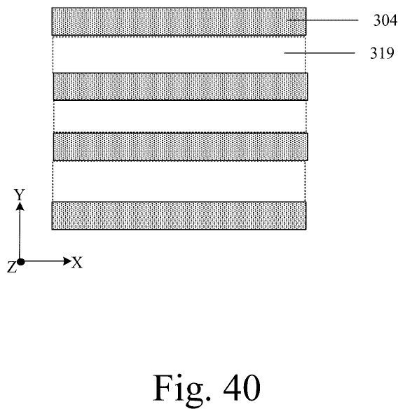

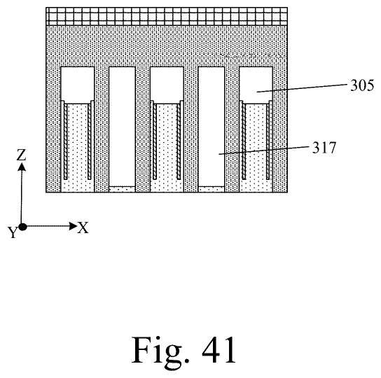

FIG. 40 is a schematic top view of the structure of FIG. 41. It is to be noted that, in order to display the bit line and the third cavity more clearly in FIG. 40, FIG. 40 is a perspective view, in which partial structures are omitted.

In some examples, a material of the metal material layer includes, but is not limited to, nickel.

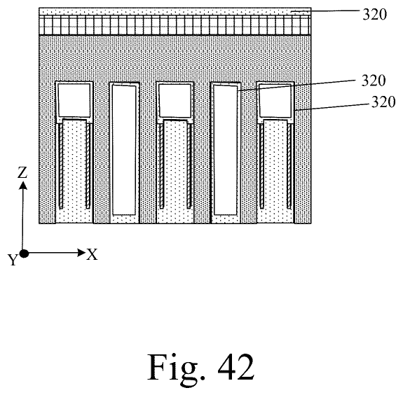

In some examples, as shown in FIG. 42, forming the first semiconductor structure further includes: after removing the third sacrificial structures 318, forming, from the first side, dielectric layers 320 on an exposed surface of the first semiconductor body 308, an exposed surface of the second semiconductor body 309, an exposed surface of the gate structure 303, and an exposed surface of the bit line 304.

In some examples, a material of the dielectric layer 320 here includes, but is not limited to, silicon oxide and silicon nitride.

In some examples, forming the first semiconductor structure further includes: forming a plurality of storage structures, where a second end of the two ends of the semiconductor body 302 that are opposite to each other along the first direction is connected to one of the storage structures.

The storage structure here includes a memory capacitor. The memory capacitor includes a first polar plate, a second polar plate, and a dielectric layer between the first polar plate and the second polar plate. In some examples, the first polar plate may be used as a lower electrode of the memory capacitor, and the second polar plate may be used as an upper electrode of the memory capacitor. A material of the dielectric layer includes a high dielectric constant (High-K) material. In an example, the material of the dielectric layer may include, but is not limited to, aluminum oxide (Al₂O₃), zirconium oxide (ZrO), hafnium oxide (HfO₂), etc. A material of the first polar plate may include a conductive material, for example, may be titanium nitride. A material of the second polar plate may include a conductive material, for example, may be titanium nitride or silicon germanium.

In some examples, the manufacturing method may further include: forming a second semiconductor structure, where the second semiconductor structure includes a peripheral circuit, and bonding the first semiconductor structure and the second semiconductor structure.

In some examples, the first semiconductor structure and the second semiconductor structure may be bonded through a hybrid bonding process.

It is to be noted that, the examples of the present disclosure are not limited to the solution of bonding the first semiconductor structure and the second semiconductor structure mentioned in the above-mentioned examples, and the first semiconductor structure and the second semiconductor structure in the present disclosure may be formed on a same wafer.

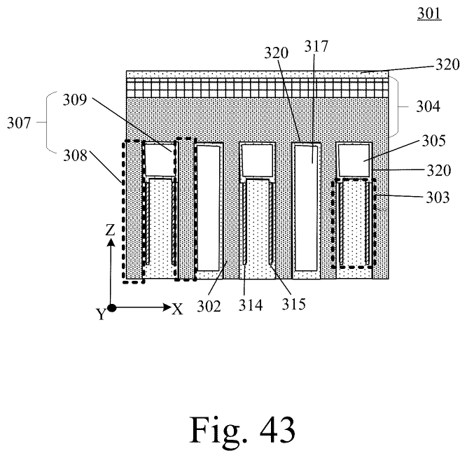

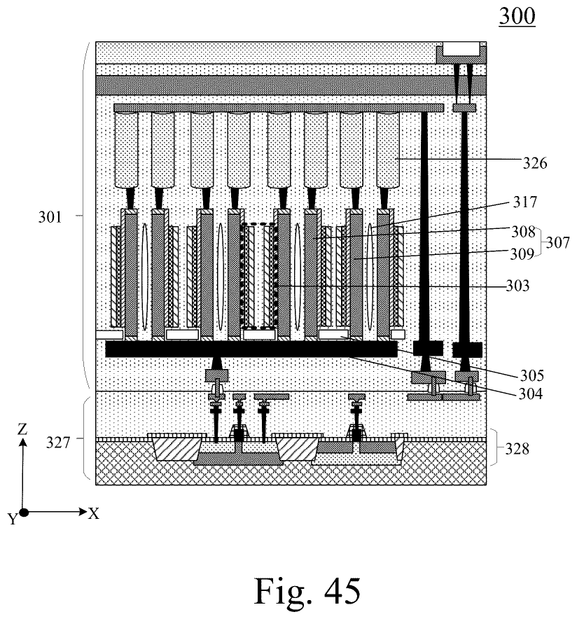

Based on a similar conception to the manufacturing method of a memory device in the above-mentioned examples, an example of the present disclosure further provides a memory device. As shown in FIGS. 43 to 45, the memory device 300 includes a first semiconductor structure 301, which includes: semiconductor bodies 302 extending along a first direction; a gate structure 303 located between the adjacent semiconductor bodies 302; a bit line 304 extending along a second direction and connected to a first end of two ends of the semiconductor body 302 that are opposite to each other along the first direction, where the first direction is perpendicular to the second direction; and a first cavity 305 located between the bit line 304 and the gate structure 303.

In an example of the present disclosure, in a first aspect, the first cavity 305 is formed between the bit line 304 and the gate structure 303 to reduce interference between transistors on two sides of the first cavity 305, such that the performance of the memory device can be improved. In a second aspect, a disconnecting process of the initial gate structure 311 is performed from a back face (first side) of the base structure 321 in respective formation methods to form the first gate layer 314 and the second gate layer 315. It is unnecessary to disconnect the initial gate structure 311 on a front face of the base structure 321, such that the process is associated with a limited complexity. In a third aspect, the first sacrificial structure 310 is first formed under the bottom portion 313 of the initial gate structure 311 from the front face (second side) of the base structure in the respective formation methods, and after the first sacrificial structure 310 is removed from the back face (first side) of the base structure 321, the disconnecting process of the initial gate structure 311 is performed, such that a height of the end, close to the bit line 304, of the two ends of the finally-formed gate structure 303 that are opposite to each other along the first direction can be controlled, e.g., by controlling a size of the first sacrificial structure 310 along the first direction, without removing a certain height of the side portion of the initial gate structure 311 from the back face of the base structure 321, causing the height of the end, close to the bit line 304, of the two ends of the finally-formed gate structure 303 that are opposite to each other along the first direction to be able to be well controlled. Furthermore, the heights of the ends, close to the bit line 304, of the two ends of different gate structures 303 that are opposite to each other along the first direction have uniformity such that the performance of the memory device is improved.

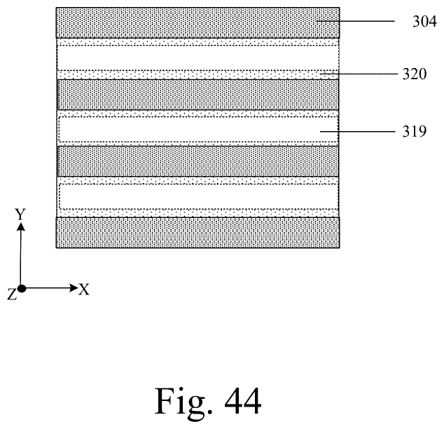

FIG. 44 is a schematic top view of the structure of FIG. 43. It is to be noted that, in order to display the bit line 304, the third cavity 319, and the dielectric layer 320 more clearly in FIG. 44, FIG. 40 is a perspective view, in which partial structures are omitted.

In some examples, a material of the bit line 304 may include a conductive material, including a metal material and a metal silicide, the metal material includes, but is not limited to, tungsten, titanium, tantalum, aluminum, etc., and the metal silicide includes, but is not limited to, tungsten silicide, nickel silicide, cobalt silicide, and titanium silicide.

In some examples, a size of the first cavity 305 along the second direction ranges from 10 nm to 60 nm, and/or a size of the first cavity 305 along the first direction ranges from 10 nm to 100 nm.

In some examples, the first semiconductor structure 301 includes the plurality of semiconductor bodies 302, the plurality of semiconductor bodies 302 constitute a plurality of semiconductor body groups 307, and the semiconductor body group 307 includes a first semiconductor body 308 and a second semiconductor body 309, which both extend along the first direction and are arranged along the second direction; the plurality of semiconductor body groups 307 are arranged in an array along the second direction and a third direction; the third direction is perpendicular to the first direction and intersects with the second direction; and the gate structure 303 extends along the third direction and is located between the first semiconductor body 308 and the second semiconductor body 309 of the semiconductor body group 307.

In some examples, the first cavity 305 extends along the third direction.

In some examples, a shape of a first surface of the gate structure 303 is curved, and the first surface is a surface, close to the bit line 304, of two surfaces of the gate structure 303 that are opposite to each other along the first direction.

It is to be noted that, the shape of the first surface of the gate structure 303 in the above-mentioned examples is for illustrative purposes only, and is not used to limit the shape of the first surface of the gate structure in the examples of the present disclosure. In the examples of the present disclosure, the bottom portion of the initial base structure is removed from the back face of the gate structure to form the gate structure, and the shape of the first surface of the gate structure may also be other shape formed by the method.

In some examples, the first semiconductor structure 301 further includes a dielectric layer 320, which is located between the first semiconductor body 308 and the second semiconductor body 309 of the semiconductor body group 307, and is located on a side surface of the first semiconductor body 308, on a side surface of the second semiconductor body 309, on a surface, close to the bit line 304, of two surfaces of the gate structure 303 that are opposite to each other along the first direction, and on a surface, close to the gate structure 303, of two surfaces of the bit line 304 that are opposite to each other along the first direction.

In some examples, a material of the dielectric layer 320 includes, but is not limited to, silicon oxide and silicon nitride.

In some examples, a shape of a surface, close to the bit line 304, of two surfaces of a portion of the dielectric layer 320 covering the gate structure 303 that are opposite to each other along the first direction is the same as a shape of the surface, close to the bit line 304, of the two surfaces of the gate structure 303 that are opposite to each other along the first direction.

In some examples, the first semiconductor structure 301 further includes a second cavity 317, which is located between adjacent two of the semiconductor body groups 307 along the second direction.

In an example of the present disclosure, the second cavity 317 is located between adjacent two of the semiconductor body groups 307 along the second direction, such that interference between the transistors on two sides of the second cavity 317 can be reduced, and interference between the gate structures 303 on the two sides of the second cavity 317 is reduced.

In some examples, a size of the second cavity 317 along the second direction ranges from 10 nm to 60 nm.

In an example of the present disclosure, when the memory device is continuously miniaturized, the size of the formed second cavity along the second direction is relatively large, thereby achieving better effects of reducing the interference between the transistors on the two sides of the second cavity 317 and reducing the interference between the gate structures 303 on the two sides of the second cavity 317.

In some examples, the dielectric layer 320 is further located between the semiconductor body groups 307 adjacent to each other along the second direction, and is located on the side surface of the first semiconductor body 308, on the side surface of the second semiconductor body 309, and on the surface, close to the gate structure 303, of the two surfaces of the bit line 304 that are opposite to each other along the first direction.

In some examples, the first semiconductor structure 301 further includes a third cavity 319, which is located between the bit lines 304 adjacent to each other along the third direction.

In an example of the present disclosure, the third cavity 319 is formed between the adjacent bit lines 304, such that the interference between the adjacent bit lines 304 can be reduced, thereby improving the performance of the memory device.

In some examples, the third cavity 319 communicates with both the second cavity 317 and the first cavity 305.

In some examples, a size of the third cavity 319 along the third direction ranges from 5 nm to 50 nm.

In some examples, the dielectric layer 320 is further located on a side surface of the bit line 304.

In some examples, the gate structure 303 includes a first gate layer 314 and a second gate layer 315 arranged in a juxtaposed manner along the second direction, where the first gate layer 314 and the second gate layer 315 both extend along the third direction.

In some examples, the gate structure 303 includes a gate and a gate insulation layer. The gate includes the first gate layer 314 and the second gate layer 315, and the first gate layer 314 and the second gate layer 315 constitutes two word lines. The first gate layer 314 and the second gate layer 315 are separated from each other through the respective dielectric layer 320. A material of the gate here includes a conductive material, such as at least one of tungsten, tantalum, titanium, nickel, platinum, titanium nitride, tungsten nitride, or tantalum nitride. A material of the gate insulation layer includes, but is not limited to, a silicon oxide, a silicon nitride, a silicon nitrogen oxide, or the like.

In some examples, the memory device 300 further includes a second semiconductor structure 327, where the first semiconductor structure 301 is stacked with the second semiconductor structure 327 along the first direction, and the second semiconductor structure 327 includes a peripheral circuit 328.

In some examples, the first semiconductor structure 301 and the second semiconductor structure 327 may be arranged in a juxtaposed manner along a direction perpendicular to the first direction, or may also be arranged in a stacking manner along the first direction. Compared to the solution that the first semiconductor structure 301 and the second semiconductor structure 327 are arranged in a juxtaposed manner along the direction perpendicular to the first direction, the first semiconductor structure 301 and the second semiconductor structure 327 being arranged in a stacking manner along the first direction can save more areas of the memory device. The first direction here may be understood as a thickness direction of the memory device, and is also an extending direction of the semiconductor body 302. The first semiconductor structure 301 and the second semiconductor structure 327 may be formed on the same wafer. Alternatively, the first semiconductor structure 301 and the second semiconductor structure 327 may be formed on different wafers, and then the first semiconductor structure 301 and the second semiconductor structure 327 are bonded, such that the first semiconductor structure 301 is stacked with the second semiconductor structure 327 along the first direction.

In some examples, the first semiconductor structure 301 further includes a plurality of storage structures 326, where a second end of the two ends of the semiconductor body 302 that are opposite to each other along the first direction is connected to the storage structure 326.

The storage structure here includes a memory capacitor. The memory capacitor includes a first polar plate, a second polar plate, and a dielectric layer between the first polar plate and the second polar plate. In some examples, the first polar plate may be used as a lower electrode of the memory capacitor, and the second polar plate may be used as an upper electrode of the memory capacitor. A material of the dielectric layer includes a high dielectric constant (High-K) material. In an example, a material of the dielectric layer may include, but is not limited to, aluminum oxide (Al₂O₃), zirconium oxide (ZrO), hafnium oxide (HfO₂), etc. A material of the first polar plate may include a conductive material, for example, may be titanium nitride. A material of the second polar plate may include a conductive material, for example, may be titanium nitride or silicon germanium.

It is to be noted that, the examples of the present disclosure are described by using an example that the memory cell includes one capacitor and one transistor (1T1C), but the present disclosure is not limited thereto. The memory cell in the present disclosure may also be an nTOC capacitor-less architecture, and the present disclosure is not limited thereto.

The memory 20 in an example of the present disclosure includes the memory device 300 in the above-mentioned examples.

Based on a similar conception to the memory in the above-mentioned examples, an example of the present disclosure further provides a memory system 30, which includes a controller 10 and the memory 20 described in any one of the above-mentioned examples. The controller 10 is configured to control the memory 20.

With respect to the above-mentioned memory system 30, FIG. 1 has already been described in detail in the aforementioned examples, and for simplicity, details are not described here again.

The features disclosed in several device examples provided by the present disclosure may be combined arbitrarily to obtain a new device example in the case of no conflicts.

The methods disclosed in several method examples provided by the present disclosure can be combined arbitrarily to obtain a new method example in case of no conflicts.

The above is only the implementations of the present disclosure, the scope of protection of the present disclosure is not limited thereto. Any variations or replacements that easily occurred to those skilled in the art within the technical scope disclosed by the present disclosure shall fall within the scope of protection of the present disclosure.

What is claimed is:

1. A memory device, comprising:
a first semiconductor structure, comprising:
a semiconductor body extending along a first direction;
a gate structure located between adjacent semiconductor bodies;
a bit line extending along a second direction and connected to a first end of two ends of the semiconductor body that are opposite to each other along the first direction, wherein the first direction is perpendicular to the second direction; and
a first cavity located between the bit line and the gate structure.

2. The memory device of claim 1, wherein a size of the first cavity along the second direction ranges from 10 nm to 60 nm, and/or a size of the first cavity along the first direction ranges from 10 nm to 100 nm.

3. The memory device of claim 1, wherein the first semiconductor structure comprises a plurality of the semiconductor bodies, which include a plurality of semiconductor body groups, the semiconductor body group comprises a first semiconductor body and a second semiconductor body, which both extend along the first direction and are arranged along the second direction, the plurality of semiconductor body groups are arranged in an array along the second direction and a third direction, the third direction is perpendicular to the first direction and intersects with the second direction; and
the gate structure extends along the third direction and is located between the first semiconductor body and the second semiconductor body of the semiconductor body group.

4. The memory device of claim 3, wherein the first cavity extends along the third direction.

5. The memory device of claim 3, wherein a shape of a first surface of the gate structure is curved, and the first surface is a surface, proximate to the bit line, of two surfaces of the gate structure that are opposite to each other along the first direction.

6. The memory device of claim 3, wherein the first semiconductor structure further comprises a dielectric layer, which is located between the first semiconductor body and the second semiconductor body of the semiconductor body group, and is located on a side surface of the first semiconductor body, on a side surface of the second semiconductor body, on a surface, proximate to the bit line, of two surfaces of the gate structure that are opposite to each other along the first direction, and on a surface, proximate to the gate structure, of two surfaces of the bit line that are opposite to each other along the first direction.

7. The memory device of claim 6, wherein the first semiconductor structure further comprises a second cavity, which is located between adjacent two of the semiconductor body groups along the second direction.

8. The memory device of claim 7, wherein a size of the second cavity along the second direction ranges from 10 nm to 60 nm.

9. The memory device of claim 7, wherein the dielectric layer is further located between the semiconductor body groups adjacent to each other along the second direction, and is located on the side surface of the first semiconductor body, on the side surface of the second semiconductor body, and on the surface, proximate to the gate structure, of the two surfaces of the bit line that are opposite to each other along the first direction; wherein the dielectric layer is further located on a side surface of the bit line; wherein the memory device further comprises a second semiconductor structure; and wherein the first semiconductor structure is stacked with the second semiconductor structure along the first direction, and the second semiconductor structure comprises a peripheral circuit.

10. The memory device of claim 7, wherein the first semiconductor structure further comprises a third cavity, which is located between the bit lines adjacent to each other along the third direction.

11. The memory device of claim 10, wherein the third cavity communicates with both the second cavity and the first cavity.

12. A method of manufacturing a memory device, comprising:
forming a first semiconductor structure, wherein the forming the first semiconductor structure comprises:
forming a semiconductor body extending along a first direction;
forming a gate structure located between adjacent semiconductor bodies;
forming a bit line, extending along a second direction and connected to a first end of two ends of the semiconductor body that are opposite to each other along the first direction, wherein the first direction is perpendicular to the second direction; and
forming a first cavity located between the bit line and the gate structure.

13. The method of claim 12, wherein:
the forming the semiconductor body and the forming the bit line comprises:
forming a plurality of semiconductor body groups and a plurality of initial bit lines, wherein the plurality of semiconductor body groups are arranged in an array along the second direction and a third direction, the semiconductor body group comprises a first semiconductor body and a second semiconductor body, which both extend along the first direction and are arranged along the second direction, the initial bit line extends along the second direction and is located on a first side of the semiconductor body group, and the second direction and the third direction intersect with each other and both are perpendicular to the first direction; and
forming the gate structure and forming the first cavity comprise:
forming a first sacrificial structure between the first semiconductor body and the second semiconductor body of the semiconductor body group from a second side, wherein the first sacrificial structure extends along the third direction, and a size of the first sacrificial structure along the first direction is less than a size of the semiconductor body group along the first direction, the first side and the second side are sides of the plurality of semiconductor body groups that are opposite to each other along the first direction;
forming an initial gate structure covering the first sacrificial structure between the first semiconductor body and the second semiconductor body of the semiconductor body group from the second side; and
removing the first sacrificial structure and a part of the initial gate structure from the first side to form the gate structure and the first cavity.

14. The method of claim 13, wherein the initial gate structure comprises two side portions and one bottom portion, the side portions extend along the first direction, the bottom portion extends along the second direction and connects the two side portions, and the removing the first sacrificial structure and the part of the initial gate structure from the first side to form the gate structure and the first cavity comprises:
removing the first sacrificial structure from the first side to expose the bottom portion of the initial gate structure, and removing the exposed bottom portion from the first side to form the first cavity and a first gate layer and a second gate layer respectively included by the two side portions.

15. The method of claim 13, wherein the forming the first semiconductor structure further comprises:
before forming the first sacrificial structure, forming a second sacrificial structure between the semiconductor body groups from the second side, wherein the second sacrificial structure extends along the third direction; and
removing the second sacrificial structure from the first side to form a second cavity.

16. The method of claim 15, wherein the removing the first sacrificial structure and the removing the second sacrificial structure are performed at the same time.

17. The method of claim 12, wherein the forming the first semiconductor structure further comprises:
before forming a metal material layer on an initial bit line from a first side, forming third sacrificial structures in the first cavity, in a second cavity, and between adjacent initial bit lines; and
after forming the bit line, removing the third sacrificial structures to form third cavities between adjacent bit lines.

18. The method of claim 17, wherein the forming the first semiconductor structure further comprises:
after removing the third sacrificial structures, forming, from the first side, dielectric layers on an exposed surface of the first semiconductor body, an exposed surface of a second semiconductor body, an exposed surface of the gate structure, and an exposed surface of the bit line.

19. The method of claim 15, wherein:
the forming the plurality of semiconductor body groups and the plurality of initial bit lines comprises:
providing a base structure, and etching the base structure from the second side to form a plurality of first grooves, wherein the plurality of first grooves all extend along the second direction and are arranged along the third direction;
etching the base structure from the second side to form a plurality of second grooves, wherein the plurality of second grooves all extend along the third direction and are arranged along the second direction;
forming a fourth sacrificial structure in the second groove; and
etching the base structure from the second side to form a plurality of third grooves, wherein the plurality of third grooves all extend along the third direction and are arranged along the second direction, and the second grooves and the third grooves are alternately arranged along the second direction, depths of the first grooves are greater than depths of the second grooves and depths of the third grooves, the first grooves, the second grooves, the third grooves divide the base structure into the plurality of semiconductor body groups and the plurality of initial bit lines;
the forming the second sacrificial structure comprises forming the second sacrificial structure in the third groove;
the forming the first semiconductor structure further comprises, after forming the second sacrificial structure, removing the fourth sacrificial structure from the second side; and
the first semiconductor structure further comprises a plurality of storage structures, and a second end of the two ends of the semiconductor body that are opposite to each other along the first direction is connected to the storage structure.

20. A memory system, comprising:
a memory device, comprising:
a semiconductor structure, comprising:
a semiconductor body extending along a first direction;
a gate structure located between adjacent semiconductor bodies;
a bit line extending along a second direction and connected to a first end of two ends of the semiconductor body that are opposite to each other along the first direction, wherein the first direction is perpendicular to the second direction; and
a first cavity located between the bit line and the gate structure; and
a controller coupled to the memory device and configured to control at least one operation of the memory device.
